(19) United States
(12) Patent Application Publication
(10) Pub. No.: US 2009/0089637 A1
(43) Pub. Date: Apr. 2, 2009

(54) Semiconductor test system and test method thereof

(75) Inventor: Soon-Kwyon Jun, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/285,003

(22) Filed: Sep. 26, 2008

(30) Foreign Application Priority Data
Sep. 27, 2007 (KR) 10-2007-097397

(51) Int. Cl. G01R 31/28; G06F 11/07

(52) U.S. Cl. 714/729; 714/E11.024

(57) ABSTRACT

Disclosed is a semiconductor test system comprised of a semiconductor integrated circuit including a plurality of scan cells arranged in first and second directions, and a scan control circuit conducting first and second test operations on the scan cells, from among the plurality of scan cells, arranged along the first and second directions, respectively, and detecting a location of a defective scan cell, from among the plurality of scan cells.

### FOREIGN PRIORITY STATEMENT

This U.S. non-provisional patent application claims priority under 35 U.S.C. §119 to Korean Patent Application No. 10-2007-97397 filed on Sep. 27, 2007, in the Korean Intellectual Property Office (KIPO), the entire contents of which are incorporated herein by reference.

### BACKGROUND

Example embodiments disclosed herein relate to semiconductor test systems and more particularly, to a semiconductor test system using a scan test circuit.

Design-For-Testability (DFS) circuits have been developed for the purpose of efficiently testing semiconductor integrated circuits. Among test methodologies for integrated circuits, DFS circuits are generally using scan test methods. The scan test is conducted for testing a semiconductor integrated circuit by means of a shift chain that is composed of one or more scan cells with flip-flops. The scan test operates to find defects of a logic circuit by repeating three steps of shift input, parallel loading, and shift output.

There are several types of scan chains, e.g., single and multiple scan chains. The single scan chain is made by forming all scan cells in a single chain. The multiple scan chain (or multi-scan chain) is configured by forming all scan cells in multiple chains. In general, the multi-scan chain is mostly used for the purpose of reducing a size of scan test vector.

FIG. 1 is a block diagram of a conventional scan test circuit. The scan test circuit shown in FIG. 1 is disclosed in Korean Patent Publication No. 10-2006-0055393, which is incorporated herein by reference.

Referring to FIG. 1, the scan test circuit includes first through fourth logic circuits LG1˜LG4, and first through third scan cells SFF1˜SFF3. The scan cells SFF1˜SFF3 are disposed between the logic circuits LG1˜LG4. Each of the logic circuits LG1˜LG4 is a combination circuit including AND or NAND circuits.

The first scan cell SFF1 is formed of a first multiplexer MPX1 and a first D flip-flop FF1. The first multiplexer MPX1 connects a data input DIN or an output of the first logic circuit LG1 to the first D flip-flop FF1 in response to a scan-enabling signal SCANEN.

The second scan cell SFF2 is formed of a second multiplexer MPX2 and a second D flip-flop FF2. The second multiplexer MPX2 connects an output of the first scan cell SFF1 or an output of the second logic circuit LG2 to the second D flip-flop FF2 in response to the scan-enabling signal SCANEN.

The third scan cell SFF3 is formed of a third multiplexer MPX3 and a third D flip-flop FF3. The third multiplexer MPX3 connects an output of the second scan cell SFF2 or an output of the third logic circuit LG3 to the third D flip-flop FF3 in response to the scan-enabling signal SCANEN.

Clock inputs C of the first through third D flip-flops FF1˜FF3 respond to a common clock supplied from a clock input terminal CLK. A selector SEL1 connects an output of the third scan cell SFF3 or an output of the fourth logic circuit LG4 to a data output DOUT in response to the scan-enabling signal SCANEN.

When the scan-enabling signal SCANEN is in logical high level, the scan test circuit is set to a shift mode. Then, the first multiplexer MPX1 selects the data input DIN and the second multiplexer MPX2 selects an output of the first scan cell SFF1. The third multiplexer MPX3 selects an output of the second scan cell SFF2. The selector SEL1 takes an output of the third scan cell SFF3 as the data output DOUT. During this, the first through third D flip-flops FF1˜FF3 constitute a shift register in which they are connected in a form of a chain. A test pattern provided from the data input DIN is transferred to the D flip-flop that is connected to an input of the logic circuit to be tested, responding to the clock signal CLK applied to the D flip-flops FF1˜FF3.

When the scan-enabling signal SCANEN is being in logical low level, the scan test circuit is set to a capture mode. Then, the first multiplexer MPX1 selects an output of the logic circuit LG1 and the second multiplexer MPX2 selects an output of the second logic circuit LG2. The third multiplexer MPX3 selects an output of the third logic circuit LG3. The selector SEL1 takes an output of the fourth logic circuit LG4 as the data output DOUT. As a test pattern is stored in the D flip-flop coupled to the logic circuit to be tested, an output of the logic circuit responding to the test pattern is transferred to the D flip-flop coupled to the logic circuit to be tested.

Thereafter, when the scan-enabling signal SCANEN goes to logical high level, an output of the logic circuit responding to the test pattern is transferred to the data output DOUT. By transferring the test pattern to the logic circuit to be tested and transferring an output of the logic circuit that responds to the test pattern, the logic circuit is tested.

However, if there is a defective one of the scan cells SFF1˜SFF3, it is difficult to normally test the logic circuit. For that reason, the scan cells SFF1˜SFF3 are verified by means of a test pattern before starting the scan test. In verifying the scan cells SFF1˜SFF3: a shift register is formed by setting the scan-enabling signal SCANEN on logical high level; a test pattern is applied to the data input DIN; and then a defective scan cell is detected by means of a tested output transferred to the data output DOUT. The test pattern is transferred to the data output DOUT through the first through third scan cells SFF1˜SFF3. Just detecting the presence of a defective scan cell from the scan cells SFF1˜SFF3, it is impossible to find a location of the defective cell. Namely, it is impossible to estimate and analyze defective scan cells, as well as disabling defects of fails to be repaired.

### SUMMARY

Example embodiments are directed to a semiconductor test system detecting positions of defective cells from a scan test circuit which includes plural scan cells.

A semiconductor test system according to an example embodiment comprises: a semiconductor integrated circuit including a plurality of scan cells arranged in first and second directions; and a scan control circuit conducting a first test operation on scan cells, from among the plurality of scan cells, arranged along the first direction, conduct a second test operation on scan cells, from among the plurality of scan cells, arranged along the second direction, and detect a location of a defective scan cell, from among the plurality of scan cells, based on the first and second test operations.

According to an example embodiment, the plurality scan cells form a plurality of first scan chains in the first direction during the first test operation, and the plurality of scan cells form a plurality of second scan chains in the second direction during the second test operation. The semiconductor integrated circuit is further comprised of input pads through which test patterns are provided from the scan control circuit in the first and second test operations. The test patterns for the first second test operations share the input pads. The semiconductor integrated circuit is further comprised of output pads through which test outputs responding to the test patterns are transferred to the scan control circuit in the first and second test operations. The test outputs of the first second test operations share the output pads.

According to an example embodiment, the semiconductor integrated circuit is further comprised of a built-in test logic circuit generating test patterns for the second test operation and discriminating a result of the test. The second test operation is conducted by the built-in test logic circuit.

According to an example embodiment, each of the plurality of scan cells includes: a D flip-flop; and a multiplexer connecting the D flip-flop to one of the first and second directions, in response to an enabling signal provided from the scan control circuit, and forming one of the first and second scan chains. The multiplexer is connected to first and second inputs to which test patterns are provided for the first and second test operations respectively, and selects one of the first and second inputs in response to the enabling signal.

A semiconductor integrated device according to an example embodiment comprises a plurality of scan cells arranged in first and second directions, the plurality of scan cells being configured to form first scan chains along the first direction for a first testing operation in response to a first enabling signal, and to form second scan chains along the second direction for a second testing operation in response to a second enabling signal.

According to an example embodiment, each of the plurality of scan cells comprises: a D flip-flop; and a multiplexer selectively connecting the D flip-flop to one of one of the first scan chains in the first direction and one of the second scan chains in the second direction, in response to the first and second enabling signals.

According to an example embodiment, the semiconductor integrated device further comprises: input pads through which test patterns for the first and second test operations are received by scan cells, from among the plurality of scan cells. The test patterns for the first and second test operations are received through the same inputs pads.

According to an example embodiment, the semiconductor integrated device further comprises: output pads through which test outputs responding to the test patterns for the first and second test operations are output from scan cells, from among the plurality of scan cells. The test outputs of the first and second test operations are output from the same output pads.

A test method for a semiconductor integrated circuit having a plurality of scan cells arranged in first and second directions according to an example embodiment comprises: testing scan cells, from among the plurality of scan cells, along the first direction; testing scan cells, from among the plurality of scan cells, along the second direction; and detecting a location of a defective scan cell, from among the plurality of scan cells, with reference to results of the tests along the first and second directions.

According to an example embodiment, testing the plural scan cells along the first direction includes: providing a first enabling signal initiating connecting the plurality scan cells in the first direction and forming a plurality of first scan chains; providing a plurality of first test patterns to the first scan chains; and receiving a plurality of first test outputs in response to the first test patterns. Testing the plurality of scan cells along the second direction includes: providing a second enabling signal initiating connecting the plural scan cells in the second direction and forming a plurality of second scan chains; providing a plurality of second test patterns to the second scan chains; and receiving a plurality of second test outputs in response to the second test patterns.

According to an example embodiment, the first and second test patterns are provided to input pads included in the semiconductor integrated circuit and the input pads are shared by the first and second test patterns. Further, the first and second test outputs are received from output pads included in the semiconductor integrated circuit and the output pads are shared by the first and second test outputs.

According to an example embodiment, the second test patterns are generated by a built-in test logic circuit included in the semiconductor integrated circuit and, a result of testing the plurality of scan cells is determined by the built-in test logic circuit. Testing the scan cells along the second direction is conducted by the built-in test logic circuit. The first enabling signal controls multiplexers included in the plurality of scan cells to form first scan chains by electrically connecting the scan cells along the first direction. The second enabling signal controls the multiplexers to form second scan chains by electrically connecting the scan cells along the second direction. The first and second test patterns are alternatively provided through the multiplexers in an alternative one of the first and second directions.

A method of operating a semiconductor integrated device during a test operation according to an example embodiment includes connecting a plurality of scan cells in a plurality of first scan chains along a first direction in response to receiving a first enabling signal; receiving a first test signal along the first scan chains; connecting the plurality of scan cells in a plurality of second scan chains along a second direction in response to receiving a second enabling signal; and receiving a second test signal along the second scan chains.

A further understanding of the nature and advantages of example embodiments may be realized by reference to the remaining portions of the specification and the attached drawings.

### BRIEF DESCRIPTION OF THE FIGURES

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a block diagram of a conventional scan test circuit;

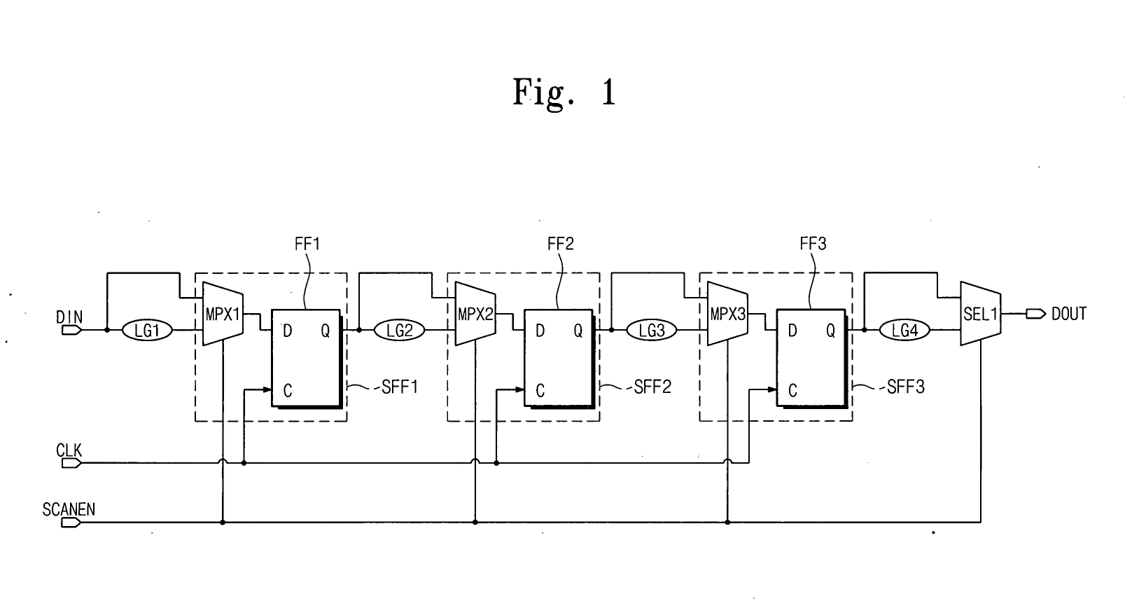

FIG. 2 is a block diagram of a semiconductor test system according to an example embodiment;

FIG. 3 is a block diagram of the semiconductor integrated circuit shown in FIG. 2;

FIG. 4 is a block diagram of a semiconductor integrated circuit to reduce the number of pads according to an example embodiment; and

FIG. 5 is a flow chart showing a test procedure for detecting a defective cell in the semiconductor test system of FIG. 2 according to an example embodiment.

### DETAILED DESCRIPTION OF PREFERRED EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Example embodiments provide a scan test circuit for detecting locations of defective cells by verifying a plurality of scan cells along first and second directions.

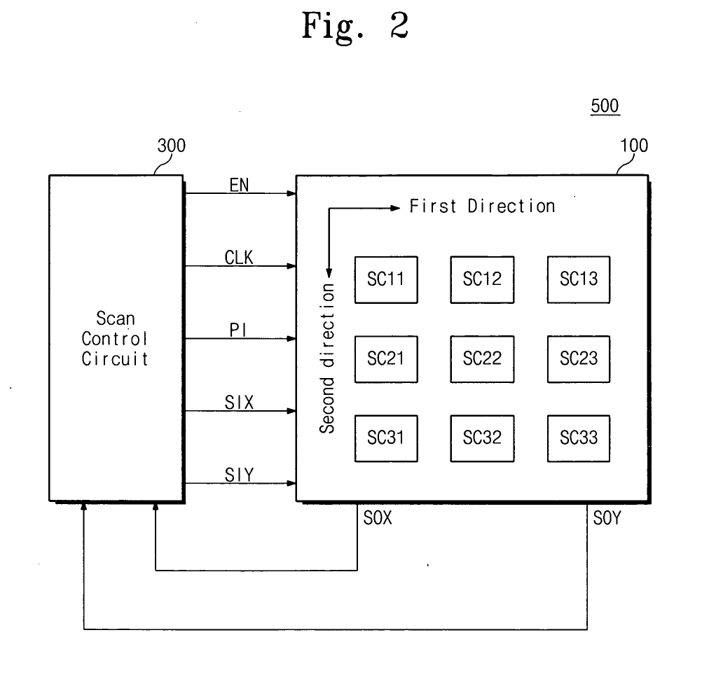

FIG. 2 is a block diagram of a semiconductor test system according to an example embodiment. Referring to FIG. 2, the semiconductor test system 500 includes a semiconductor integrated circuit 100 and a scan control circuit 300. The scan control circuit 300 may be connected to the semiconductor integrated circuit 100 through pads.

The semiconductor integrated circuit 100 includes a plurality of logic circuits (not shown) and a scan test circuit which is composed of scan cells SC11˜SC33 for conducting a scan test operation on the plurality logic circuits. The scan cells SC11˜SC33 may be verified (or tested) before the scan test. If there is a defective one of the scan cells SC11˜SC33, it is difficult or impossible to normally conduct the scan test.

The scan control circuit 300 operates to control the semiconductor memory device 100 so as to test the scan cells SC11˜SC33. The scan control circuit 300 applies an enabling signal EN to the semiconductor integrated circuit 100 so as to connect the scan cells SC11˜SC33 in the first direction (e.g., row direction). For instance, the scan cells SC11, SC12, and SC13 form a unit scan chain; the scan cells SC21, SC22, and SC23 form a unit scan chain; and the scan cells SC31, SC32, and SC33 form a unit scan chain.

The scan control circuit 300 provides test patterns to the semiconductor integrated circuit 100 through scan inputs SIX of the first direction. If a clock signal CLK is applied to the semiconductor integrated circuit 100, the test patterns are shifted along the scan chains. The scan control circuit 300 receives scan outputs SOX of the first direction as test outputs, and then detect a defective cell. For example, if the scan cell SC22 is a defective cell, a test output transferred through the scan outputs SOX of the first direction from the scan chain of the scan cells SC21˜SC23 is different from a desired value (or alternatively, a predetermined value) of the test output. This occurs because the test pattern has changed while passing through the defective scan cell SC22. Thereby, the test along the first direction makes it possible to determine whether there is a defective one in the scan cells SC21˜SC23. Namely, receiving a value different than the desired value through the scan output SOX of the first scan chain along the first direction including scan cells SC21˜SC23 indicates that an error exists in at least one of scan cells SC21˜SC23.

The scan control circuit 300 applies the enabling signal EN to the semiconductor integrated circuit 100 so as to connect the scan cells SC11˜SC33 in a second direction (e.g., column direction). For instance, the scan cells SC11, SC21, and SC31 form a unit scan chain; the scan cells SC12, SC22, and SC32 form a unit scan chain; and the scan cells SC13, SC23, and SC33 form a unit scan chain.

The scan control circuit 300 provides test patterns to the semiconductor integrated circuit 100 through scan inputs SIY of the second direction. If a clock signal CLK is applied to the semiconductor integrated circuit 100, the test patterns are shifted along the scan chains. The scan control circuit 300 receives scan outputs SOY of the second direction as test outputs, and then detects a defective cell. For example, if the scan cell SC22 is a defective cell, a test output transferred through the scan outputs SOX of the first direction from the scan chain of the scan cells SC12˜SC32 is different from a desired value (or alternatively, a predetermined value) of the test output. This occurs because the test pattern has changed while passing through the defective scan cell SC22. Thereby, the test along the second direction makes it possible to determine whether there is a defective one in the scan cells SC12˜SC32. Namely, receiving a value different than the desired value through the scan output SOY of the second scan chain along the second direction including scan cells SC12˜SC32 indicates that an error exists in at least one of scan cells SC12˜SC32. Combining the result of the first test operation indicating an error in scan cells SC21˜SC23 with the result of the second test indicating an error in scan cells SC12˜SC32, scan cell SC22, the only scan cell included in both first scan chain SC12˜SC32 and second scan chain SC12˜SC32, is identified as the defective scan cell.

With reference to test results along the first and second directions, semiconductor test system 500 determine the scan cell SC22 is defective. As a result, the semiconductor test system 500 according to this example embodiment is able to detect a position of the defective scan cell, as well as the presence of the defective scan cell.

After the test of the first direction, if there is no detection of a defective cell, a scan test is carried out on the logic circuits of the semiconductor integrated circuit 100. Test patterns for the scan test are provided to the semiconductor integrated circuit 100 through primary inputs PI.

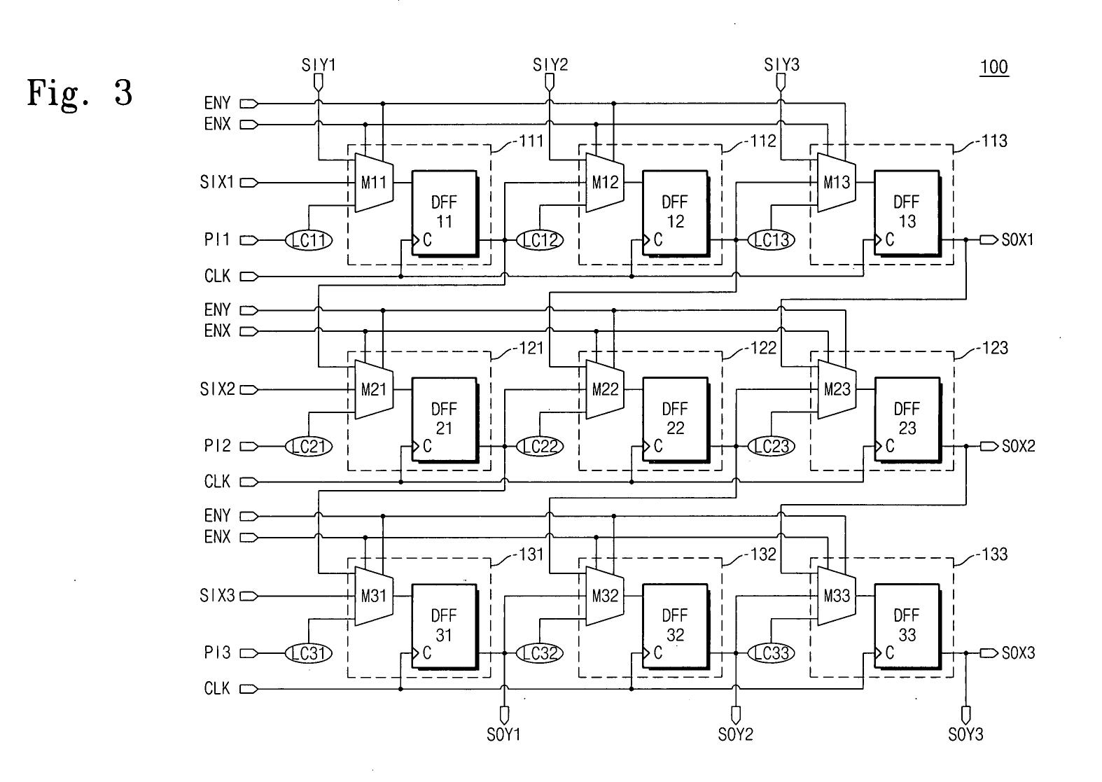

FIG. 3 is a block diagram of the semiconductor integrated circuit 100 shown in FIG. 2. Referring to FIG. 3, the semiconductor integrated circuit 100 according to an example embodiment include a plurality of logic circuits LC11˜LC33 and a plurality of scan cells 111˜133. The example illustrated in FIG. 3 shows the scan cells 111˜333 arranged in the first and second directions. Each of the scan cells 111˜133 is formed of multiplexers M11˜M33 and D flip-flops DFF1˜DFF33.

The logic circuit LC11 accepts data from a first primary input PI1 and provides an operation result to the scan cell 111. The scan cell 111 selects one from an output of the logic circuit LC11, a first scan input SIX1 of the first direction, and a first scan input SIY1 of the second direction in response to first and second enabling signals ENX and ENY. The scan cell 111 includes the multiplexer M11 and the D flip-flop DFF11. The multiplexer M11 selects one from an output of the logic circuit LC11, the first scan input SIX1 of the first direction, and the first scan input SIY1 of the second direction in response to the first and second enabling signals ENX and ENY, and connects a selected data path to the D flip-flop DFF11.

For example, if the first enabling signal ENX and the second enabling signal ENY are logically low level, the multiplexer M11 selects an output of the logic circuit LC11. If the first enabling signal ENX is logically high level and the second enabling signal ENY is logically low level, the multiplexer M11 selects the first scan input SIX1 of the first direction. If the second enabling signal ENY is logically high level and the first enabling signal ENX is logically low level, the multiplexer M11 selects the first scan input SIY1 of the second direction. The D flip-flop DFF11 holds data provided from the multiplexer M11, responding to the clock signal CLK. An output of the scan cell 111 is transferred to the logic circuit LC12, the scan cell 112, and the scan cell 121.

The scan cell 112 selects one from an output of the logic circuit LC12, an output of the scan cell 111, and the second scan input SIY2 of the second direction in response to the first and second enabling signals ENX and ENY. The scan cell 112 includes the multiplexer M12 and the D flip-flops DFF11˜DFF33. The multiplexers M11˜M33 and the D flip-flops DFF11˜DFF33 are the same and operate in respectively the same manner with the same structure, so, for convenience, they will not be further described. An output of the scan cell 112 is transferred to the logic circuit LC13, the scan cell 113, and the scan 122.

The scan cell 113 selects one from an output of the logic circuit LC13, an output of the scan cell 112, and the third scan input SIY3 of the second direction in response to the first and second enabling signals ENX and ENY. The scan cell 113 includes the multiplexer M13 and the D flip-flop DFF13. An output of the scan cell 113 is transferred to the first scan output SOX1 and the scan cell 123.

The scan cell 121 selects one from an output of the logic circuit LC21, the second scan input SIX2 of the first direction, and an output of the scan cell 111 in response to the first and second enabling signals ENX and ENY. The scan cell 121 includes the multiplexer M21 and the D flip-flop DFF21. An output of the scan cell 121 is transferred to the logic circuit LC22, the scan cell 122, and the scan cell 131.

The scan cell 122 selects one from an output of the logic circuit LC22, an output of the scan cell 211, and an output of the scan cell 112 in response to the first and second enabling signals ENX and ENY. The scan cell 122 includes the multiplexer M22 and the D flip-flop DFF22. An output of the scan cell 122 is transferred to the logic circuit LC23, the scan cell 123, and the scan cell 132.

The scan cell 123 selects one from an output of the logic circuit LC23, an output of the scan cell 122, and an output of the scan cell 113 in response to the first and second enabling signals ENX and ENY. The scan cell 123 includes the multiplexer M23 and the D flip-flop DFF23. An output of the scan cell 123 is transferred to the second scan output SOY2 of the first direction, and the scan cell 133.

The scan cell 131 selects one from an output of the logic circuit LC31, the third scan input SIX3 of the first direction, and an output of the scan cell 121 in response to the first and second enabling signals ENX and ENY. The scan cell 131 includes the multiplexer M31 and the D flip-flop DFF31. An output of the scan cell 131 is transferred to the logic circuit LC32, the scan cell 132, and the first scan output SOY1 of the second direction.

The scan cell 132 selects one from an output of the logic circuit LC32, an output of the scan cell 131, and an output of the scan cell 122 in response to the first and second enabling signals ENX and ENY. The scan cell 132 include the multiplexer M32 and the D flip-flop DFF32. An output of the scan cell 132 is transferred to the logic circuit LC33, the scan cell 133, and the second scan output SOY2 of the second direction.

The scan cell 133 selects one from an output of the logic circuit LC33, an output of the scan cell 132, and an output of the scan cell 123 in response to the first and second enabling signals ENX and ENY. The scan cell 133 includes the multiplexer M33 and the D flip-flop DFF33. An output of the scan cell 133 is transferred to the third scan output SOX3 of the first direction, and the third scan output SOY3 of the second direction.

The scan test circuit of the semiconductor integrated circuit 100 is connected to the scan control circuit 300. In general, the scan control circuit 300 is included in a tester external to the semiconductor integrated circuit 100, for verifying the scan test circuit. The scan control circuit 300 conducts the test operation by providing the scan test circuit with the first and second enabling signals ENX and ENY, the first-direction scan inputs SIX1˜SIX3, the second-direction scan inputs SIY1˜SIY3, the primary inputs PI1˜PI3, and the clock signal CLK. The scan control circuit 300 receives the first-direction scan outputs SOX1˜SOX3 and the second-direction scan outputs SOY1˜SOY3 from the scan test circuit and detects defects of the scan cells 111˜133 and the logic circuits LC11˜LC133.

The semiconductor test system according to an example embodiment is able to detect a position of a defective scan cell by testing the scan cells 111˜133 in the first and second directions. Hereinafter a method of detecting a position of a defective cell by the semiconductor test system according to an example embodiment will be described with reference to FIG. 3. For the purposes of explaining this example embodiment, it is assumed that the first direction corresponds to a row direction, the second direction corresponds to a column direction and the scan cell 122 is a defective cell.

If the first enabling signal ENX is logically high level, a scan chain is formed by way of the first scan input SIX1 of the first direction and includes the scan cell 111, the scan cell 112, the scan cell 113, and the first scan output SOX1 of the first direction. A scan chain is formed by way of the second scan input SIX2 of the first direction and includes the scan cell 121, the scan cell 122, and the scan cell 123, and the second scan output SOX2 of the first direction. A scan chain is formed by way of the third scan input SIX3 of the first direction and includes the scan cell 131, the scan cell 132, the scan cell 133, and the third scan output SOX3 of the first direction. The scan cells 111˜133 form the scan chains along the first direction. A test pattern is provided to the first-direction scan inputs SIX1˜SIX3. If the clock signal CLK is applied to the scan cells 111˜133, the test pattern is shifted along the scan chains of the first direction.

An output transferred from the first scan output SOX1 of the first direction matches with a desired test output (or alternatively, a predetermined test output). An output transferred from the third scan output SOX3 of the first direction matches with a desired test output (or alternatively, a predetermined test output). But, an output transferred from the second scan output SOX2 of the first direction mismatches to a desired test output (or alternatively, a predetermined test output). This variation of the second scan output SOX2 occurs because there is variation of the test pattern due to a defect of the scan cell 122 while the test pattern is shifting through the scan cells 121, 122, and 123.

As a defect cell is detected through the test with the first-direction scan chains, the next test operation begins with the second-direction scan chains. If the second enabling signal ENY is logically high level, a scan chain is formed by way of the first scan input SIY1 of the second direction, the scan cell 111, the scan cell 121, the scan cell 131, and the first scan output SOY1 of the second direction. A scan chain is formed by way of the second scan input SIY2 of the second direction, the scan cell 112, the scan cell 122, and the scan cell 132, and the second scan output SOY2 of the second direction. A scan chain is formed by way of the third scan input SIY3 of the second direction, the scan cell 113, the scan cell 123, the scan cell 133, and the third scan output SOY3 of the second direction.

An output transferred from the first scan output SOY1 of the second direction matches with a desired test output (or alternatively, a predetermined test output). An output transferred from the third scan output SOY3 of the second direction matches with a desired test output (or alternatively, a predetermined test output). But, an output transferred from the second scan output SOY2 of the second direction does not match with a desired test output (or alternatively, a predetermined test output). This variation of the second scan output SOY2 occurs because there is variation of the test pattern due to a defect of the scan cell 122 while the test pattern is shifting through the scan cells 121, 122, and 132.

The test operation along the first direction detects a defective cell between the second scan input SIX2 of the first direction and the second scan output SOX2 of the first direction. The test operation along the second direction detects a defective cell between the second scan input SIY2 of the second direction and the second scan output SOY2 of the second direction. As a result, it is able to determine the defective cell is the scan cell 122. Finding a location of the defective scan cell by such a procedure, it is possible to process defect analysis and repair defects.

According to an example embodiment, the semiconductor integrated circuit 100 is disposed on a wafer which includes pads for test. The semiconductor test system 500 transfers the test pattern, the enabling signals, and the clock signal to the semiconductor integrated circuit 100 through the pads. The semiconductor test system 500 receives test outputs from the semiconductor integrated circuit 100 through the pads and detects a defect of the semiconductor integrated circuit 100. If the size of the pads is too small, the size of the pads makes it difficult to connect the semiconductor integrated circuit 100 with an external test system or a tester. Therefore, the pads are formed larger than a reference size (or alternatively, a predetermined size) in order to ensure a desired level of connectivity between the semiconductor integrated circuit 100 and the external test system or tester. The chip of the semiconductor integrated circuit increases in size as the number and size of the pads increases.

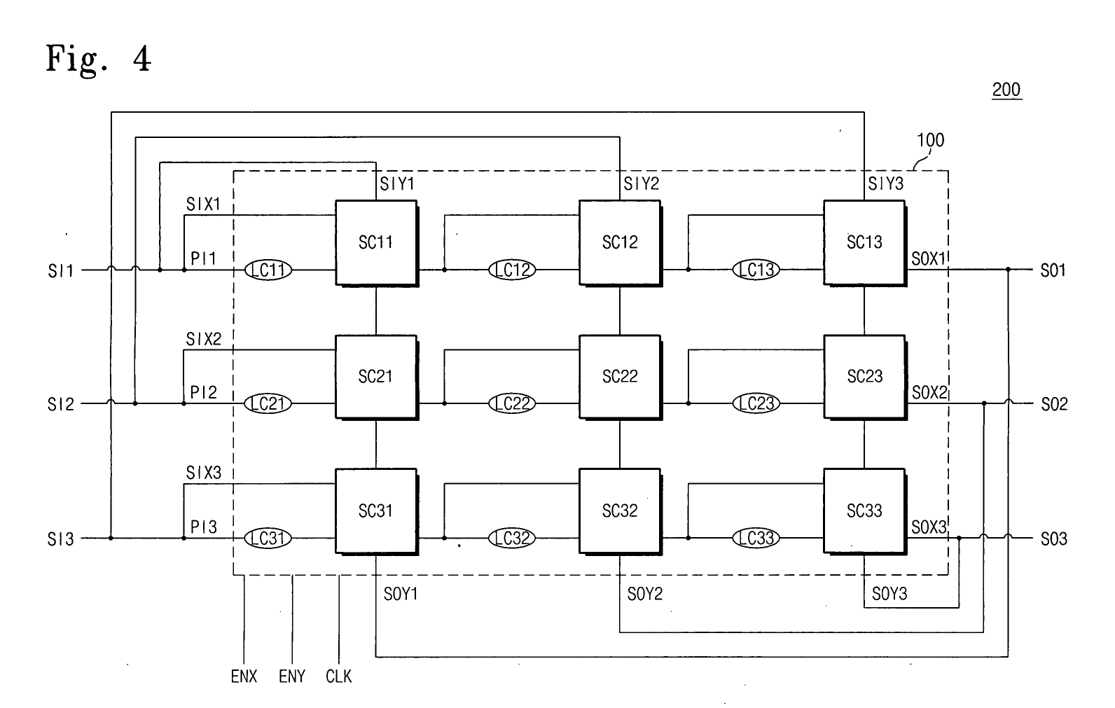

FIG. 4 is a block diagram of a semiconductor integrated circuit to reduce a number of the pads according to an example embodiment. FIG. 4 shows a semiconductor integrated circuit 200 with inputs PI1˜PI3, SIX1˜SIX3, and SIY1˜SIY3; outputs SOX1˜SOX3 and SOY1˜SOY3; enabling signals ENX and ENY; and a clock signal CLK. Referring to FIG. 4, the semiconductor integrated circuit 200 includes scan cells SC11˜SC33 and logic circuits LC11˜LC33. The structural and operational features of the scan cells SC11˜SC33 and the logic circuits LC11˜LC33 are respectively the same as those of the semiconductor integrated circuit 100 shown in FIG. 3, so the features will not be further detailed.

As FIG. 4 illustrates, the first and second enabling signals ENX and ENY, and the clock signal CLK are shared by all of the scan cells SC11˜SC33. Thus, the first and second enabling signals ENX and ENY and the clock signal CLK are provided from the scan control circuit 300 by way of the pads respectively.

In testing the logic circuits LC11˜LC33, the primary inputs PI1˜PI3 and the first-direction scan outputs SOX1˜SOX3 are selected in response to the first enabling signal ENX. In testing the scan cells along the first direction, the first-direction scan inputs and outputs SIX1˜SIX3 and SOX1˜SOX3 are selected in response to the first enabling signals ENX. In testing the scan cells along the second direction, the second-direction scan inputs and outputs SIY1˜SIY3 and SOY1˜SOY3 are selected in response to the second enabling signals ENY. According to an example embodiment, while verifying (i.e., testing) the scan test circuit 200, the primary inputs PI1˜PI3, the first-direction scan inputs SIX1˜SIX3 and the second-direction scan inputs SIY1˜SIY3 are not activated at the same time. Additionally, the first-direction scan outputs SOX1˜SOX3 and the second-direction scan outputs SOY1˜SOY3 are not activated at the same time. Thus, it is permissible for the primary inputs PI1˜PI3, the first-direction scan inputs SIX1˜SIX3 and the second-direction scan inputs SIY1˜SIY3 to share one pad. Additionally, the first-direction scan outputs SOX1˜SOX3 and the second-direction scan outputs SOY1˜SOY3 are able to share one pad.

Referring to FIG. 4, the first primary input PI1, the first scan input SIX1 of the first direction, and the first scan input SIY1 of the second direction are connected to a pad through the first scan input SI1; the second primary input PI2, the second scan input SIX2 of the first direction, and the second scan input SIY2 of the second direction are connected to a pad through the second scan input SI2; and the third primary input PI3, the third scan input SIX3 of the first direction, and the third scan input SIY3 of the second direction are connected to a pad through the third scan input SI3. Additionally, the first scan output SOX1 of the first direction and the first scan output SOY1 of the second direction are connected to a pad through the first scan output SO1; the second scan output SOX2 of the first direction and the second scan output SOY2 of the second direction are connected to a pad through the second scan output SO2; and the third scan output SOX3 of the first direction and the third scan output SOY3 of the second direction are connected to a pad through the third scan output SO3. As a result, it is possible to detect a location of a defective cell, without increasing the number of pads, by providing multiple signals, which are needed by the scan test circuit of the semiconductor integrated circuit 200, through single pads.

According to an example embodiment, the scan test circuit includes a built-in test logic circuit. The built-in test logic circuit is formed in the semiconductor integrated circuit and provides a test pattern to the scan test circuit and detects a defect with reference to tested outputs transferred from the scan test circuit. The second-direction scan chains are formed in a shift register including multiplexers and flip-flops which are connected to each other in series. Thus, it is possible to detect a defective cell by means of a simple test pattern. Namely, the built-in test logic circuit for verifying the second-direction scan chain may be implemented in a simple structure and occupy a small space in the semiconductor integrated circuit.

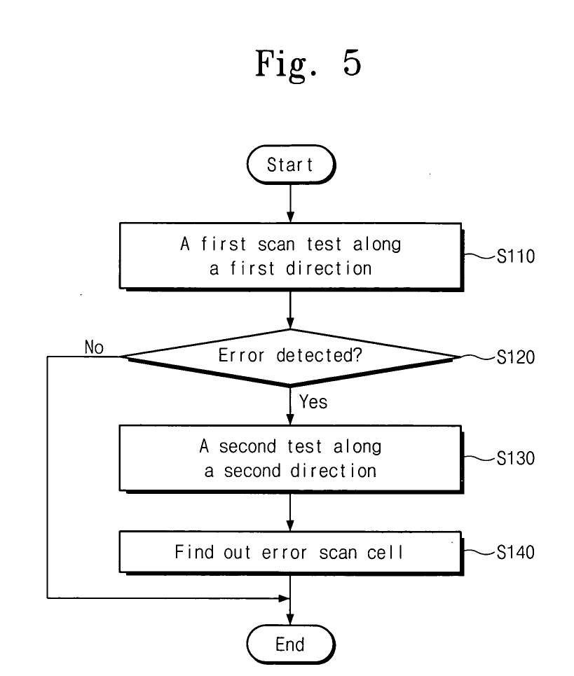

FIG. 5 is a flow chart showing a test procedure for detecting a defective cell in the semiconductor test system of FIG. 2. Referring to FIGS. 2 and 5, a first scan test is carried out along the first direction in a step S110. The scan control circuit 300 sets the first enabling signal ENX on a logically high level. Then, the scan cells 111˜133 form the first-direction scan chains between the first-direction scan inputs SIX1˜SIX3 and the first-direction scan outputs SOX1˜SOX3. Once test patterns are provided to the first-direction scan inputs SIX1˜SIX3 from the scan control circuit 300, the test patterns are shifted through the first-direction scan chains and to the first-direction scan outputs SOX1˜SOX3. In step S120, the scan control circuit 300 uses the scan outputs SOX1˜SOX3 to detect a defective scan cell Unless there is a defective scan cell, the scan control circuit 300 terminates the test operation for the scan cells. If there is a defective scan cell, the procedure proceeds to a step S130 for detecting a location of the defective cell.

In step S130 the scan control circuit 300 or the built-in test logic circuit conducts a second scan test along the second direction. The scan control circuit 300 or the built-in test logic circuit sets the second enabling signal ENY on logically high level. Then, the scan cells 111˜133 form the second-direction scan chains between the second-direction scan inputs SIY1˜SIY3 and the second-direction scan outputs SOY1˜SOY3. Once test patterns are provided to the second-direction scan inputs SIY1˜SIY3 from the scan control circuit 300 and the built-in test logic circuit, the test patterns are shifted through the second-direction scan chains. If test outputs are transferred from the second-direction scan outputs SOY1˜SOY3, the scan control circuit 300 determines a location of the defective scan cell (S140).

Though the examples depicted in FIGS. 2, 3 and 4 illustrate a semiconductor integrated circuit comprised of the nine scan cells and logic circuits, which are arranged along the first and second directions, a semiconductor integrated circuit according to example embodiments may include any number of scan cells and logic circuits.

In the examples depicted in FIGS. 2, 3 and 4 it was assumed that the first direction corresponds to the row direction while the second direction corresponds to the column direction. However, according to example embodiments, as interconnections of the semiconductor integrated circuit are formed in a multi-layer structure, the disposition of the scan cells connected with each other may not be restrictive to an arrangement where the first and second directions are each assigned to the row and column directions, respectively. According to example embodiments, the first and second directions are related rather in electrical disposition than physical disposition.

As aforementioned, the semiconductor test system according to example embodiments is able to detect locations of defective cells by verifying scan cells of the scan test circuit along the first and second directions. Thereby, it is possible to analyze defects in scan cells, enhancing a product yield of semiconductor integrated circuits. Moreover, the semiconductor test system according to employs the scan test circuit capable of finding locations of defective cells without additional pads. Therefore, the semiconductor test system according to example embodiments it prevents a dimensional increase of a semiconductor chip due to the scan test circuit for detecting defective cell locations.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A semiconductor test system comprising:
a semiconductor integrated circuit including a plurality of scan cells arranged in first and second directions; and
a scan control circuit conducting a first test operation on scan cells, from among the plurality of scan cells, arranged along the first direction, conducting a second test operation on scan cells, from among the plurality of scan cells, arranged along the second direction, and detecting a location of a defective scan cell, from among the plurality of scan cells based on the first and second test operations.

2. The semiconductor test system as set forth in claim 1, wherein the plurality of scan cells form a plurality of first scan chains in the first direction during the first test operation, and the plurality of scan cells form a plurality of second scan chains in the second direction during the second test operation.

3. The semiconductor test system as set forth in claim 2, wherein the semiconductor integrated circuit further comprises input pads through which test patterns are provided from the scan control circuit in the first and second test operations, and the test patterns for the first and second test operations share the input pads.

4. The semiconductor test system as set forth in claim 3, wherein the semiconductor integrated circuit further comprises output pads through which test outputs responding to the test patterns are transferred to the scan control circuit in the first and second test operations,
wherein the test outputs of the first and second test operations share the output pads.

5. The semiconductor test system as set forth in claim 2, wherein the semiconductor integrated circuit further comprises a built-in test logic circuit generating test patterns for the second test operation and discriminating a result of the second test operation,
wherein the second test operation is conducted by the built-in test logic circuit.

6. The semiconductor test system as set forth in claim 2, wherein each of the plurality scan cells comprises:
a D flip-flop; and
a multiplexer connecting the D flip-flop to one of the first and second directions, in response to an enabling signal provided from the scan control circuit, and forming one of the first and second scan chains.

7. The semiconductor test system as set forth in claim 6, wherein the multiplexer is connected to first and second inputs to which test patterns are provided for the first and second test operations, respectively, and selects one of the first and second inputs in response to the enabling signal.

8. A semiconductor integrated device comprising:
a plurality of scan cells arranged in first and second directions, the plurality of scan cells being configured to form first scan chains along the first direction for a first testing operation in response to a first enabling signal, and to form second scan chains along the second direction for a second testing operation in response to a second enabling signal.

9. The semiconductor integrated device as set forth in claim 8, wherein each of the plurality scan cells comprises:
a D flip-flop; and
a multiplexer selectively connecting the D flip-flop to one of one of the first scan chains in the first direction and one of the second scan chains in the second direction, in response to the first and second enabling signals.

10. The semiconductor integrated device as set forth in claim 8, further comprising:
input pads through which test patterns for the first and second test operations are received by scan cells, from among the plurality of scan cells, the test patterns for the first and second test operations being received through the same inputs pads.

11. The semiconductor integrated device as set forth in claim 10, further comprising:
output pads through which test outputs responding to the test patterns for the first and second test operations are output from scan cells, from among the plurality of scan cells, the test outputs of the first and second test operations being output from the same output pads.

12. A test method for testing a semiconductor integrated circuit having a plurality of scan cells arranged in first and second directions, the method comprising:
testing the scan cells, from among the plurality of scan cells, along the first direction;
testing the scan cells, from among the plurality of scan cells, along the second direction; and
detecting a location of a defective scan cell, from among the plurality of scan cells, with reference to results of the tests along the first and second directions.

13. The method as set forth in claim 12, wherein testing the plural scan cells along the first direction includes
providing a first enabling signal initiating connection of the plurality scan cells in the first direction and forming a plurality of first scan chains,
providing a plurality of first test patterns to the first scan chains, and
receiving a plurality of first test outputs in response to the first test patterns.

14. The method as set forth in claim 13, wherein testing the plurality of scan cells along the second direction includes
providing a second enabling signal initiating connection of the plurality of scan cells in the second direction and forming a plurality of second scan chains,
providing a plurality of second test patterns to the second scan chains, and
receiving a plurality of second test outputs in response to the second test patterns.

15. The method as set forth in claim 13, wherein the first and second test patterns are provided to input pads included in the semiconductor integrated circuit, the input pads being shared by the first and second test patterns.

16. The method as set forth in claim 15, wherein the first and second test outputs are received from output pads included in the semiconductor integrated circuit, the output pads being shared by the first and second test outputs.

17. The method as set forth in claim 13, wherein the second test patterns are generated by a built-in test logic circuit included in the semiconductor integrated circuit and, a result of testing the plurality of scan cells is determined by the built-in test logic circuit,
the testing of the scan cells along the second direction being conducted by the built-in test logic circuit.

18. The method as set forth in claim 13, wherein the first enabling signal controls multiplexers included in the plurality of scan cells to form first scan chains by electrically connecting the scan cells along the first direction, and
the second enabling signal controls the multiplexers to form second scan chains by electrically connecting the scan cells along the second direction.

19. The method as set forth in claim 18, wherein the first and second test patterns are alternatively provided through the multiplexers in an alternative one of the first and second directions.

20. A method of operating a semiconductor integrated device during a test operation comprising:
connecting a plurality of scan cells in a plurality of first scan chains along a first direction in response to receiving a first enabling signal;
receiving a first test signal along the first scan chains;
connecting the plurality of scan cells in a plurality of second scan chains along a second direction in response to receiving a second enabling signal; and
receiving a second test signal along the second scan chains.
